(19) United States
(12) Patent Application Publication
(10) Pub. No.: US 2026/0005673 A1
(43) Pub. Date: Jan. 1, 2026

(54) BULK ACOUSTIC WAVE DEVICE WITH CAPACITOR

(71) Applicant: Skyworks Global Pte. Ltd., Singapore (SG)

(72) Inventors: Yanbo He, Irvine, CA (US); Kwang Jae Shin, Yongin-si (KR); Zongliang Cao, Irvine, CA (US); Li Chen, Irvine, CA (US); Stefan Bader, Fort Collins, CO (US); Nobufumi Matsuo, Suita-Shi (JP); Alexandre Augusto Shirakawa, Cardiff by the Sea, CA (US)

(21) Appl. No.: 19/244,359

(22) Filed: Jun. 20, 2025

Related U.S. Application Data
(60) Provisional application No. 63/665,978, filed on Jun. 28, 2024.
(60) Provisional application No. 63/666,033, filed on Jun. 28, 2024.

(51) Int. Cl. H03H 9/56; H03H 9/02; H03H 9/13; H03H 9/17

(52) U.S. Cl. CPC H03H 9/568; H03H 9/0211; H03H 9/133; H03H 9/17

(57) ABSTRACT

Aspects of this disclosure relate to a bulk acoustic wave resonator and an integrated capacitor. In certain embodiments, the integrated capacitor can be a metal-insulator-metal capacitor in parallel with the bulk acoustic wave resonator. The metal-insulator-metal capacitor can include a portion of a first electrode and a portion of a second electrode of the bulk acoustic wave resonator. At least part of the metal-insulator-metal capacitor is positioned laterally relative to an acoustic reflector of the bulk acoustic wave resonator. Other embodiments of capacitors integrated with a bulk acoustic wave resonator are disclosed. Related filters, multiplexers, radio frequency modules, radio frequency systems, wireless communication devices, and methods are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/665,978, filed Jun. 28, 2024 and titled “BULK ACOUSTIC WAVE DEVICE WITH CAPACITOR,” and claims the benefit of priority of U.S. Provisional Application No. 63/666,033, filed Jun. 28, 2024 and titled “CAPACITOR INTEGRATED WITH BULK ACOUSTIC WAVE RESONATOR,” the disclosures of each of which are hereby incorporated by reference in their entireties and for all purposes.

### BACKGROUND

### Technical Field

The disclosed technology relates to acoustic wave devices. Embodiments of this disclosure relate to bulk acoustic wave resonator structures including a capacitor integrated with a bulk acoustic wave resonator.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to increasing Q and further suppressing spurious mode(s) while meeting other performance specifications for BAW devices.

There are technical challenges related to meeting certain filter specifications with acoustic wave filters. For example, filters with steep skirts and relatively low insertion loss near band edges are typically desirable. Meeting certain filter specifications related to skirt steepness and/or low insertion loss while also meeting other filter specifications can be challenging.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave resonator structure that includes a bulk acoustic wave resonator and a metal-insulator-metal capacitor in parallel with the bulk acoustic wave resonator. The bulk acoustic wave resonator includes an acoustic reflector, a first electrode, a second electrode, a piezoelectric layer positioned between the first electrode and the second electrode, and a frame structure. The metal-insulator-metal capacitor includes a portion of the first electrode and a portion of the second electrode. At least part of the metal-insulator-metal capacitor is positioned laterally relative to the acoustic reflector.

The metal-insulator-metal capacitor can include an engineered region of the piezoelectric layer positioned between the portion of the first electrode and the portion of the second electrode. The engineered region of the piezoelectric layer can have a lower magnitude effective piezoelectric coefficient than the piezoelectric layer in an acoustically active region of the bulk acoustic wave resonator.

The frame structure can at least partially overlap the metal-insulator-metal capacitor. The frame structure can include a raised frame structure. The frame structure can be asymmetric about an acoustically active region of the bulk acoustic wave resonator. The frame structure can fully overlap with an insulator of the metal-insulator-metal capacitor.

The bulk acoustic wave resonator structure can include an interconnect structure at least partially over the metal-insulator-metal capacitor.

The bulk acoustic wave resonator structure can include a second metal-insulator-metal capacitor in series with the bulk acoustic wave resonator. The second metal-insulator-metal capacitor and the bulk acoustic wave resonator can be over a common substrate such that (i) the acoustic reflector is between the common substrate and the piezoelectric layer of the bulk acoustic wave resonator and (ii) the bulk acoustic wave resonator structure is free from the acoustic reflector between the second metal-insulator-metal capacitor and the common substrate.

The acoustic reflector can be an air cavity.

Another aspect of this disclosure is a bulk acoustic wave resonator structure that includes a bulk acoustic wave resonator and a capacitor. The bulk acoustic wave resonator includes an acoustic reflector, a resonator portion of a first electrode, a resonator portion of a second electrode, a piezoelectric layer positioned between the resonator portion of the first electrode and the resonator portion of the second electrode, and a frame structure. The capacitor includes a capacitor portion of the first electrode, a capacitor portion of the second electrode, and an insulator positioned between the capacitor portion of the first electrode and the capacitor portion of the second electrode. At least part of the insulator overlaps with the frame structure. Aat least part of the capacitor is positioned laterally relative to the acoustic reflector.

The insulator can include an engineered region of the piezoelectric layer. The engineered region of the piezoelectric layer can have a lower magnitude effective piezoelectric coefficient than the piezoelectric layer between the resonator portion of the first electrode and the resonator portion of the second electrode.

The frame structure can fully overlap the insulator. The frame structure can include a raised frame structure.

The bulk acoustic wave resonator structure can include an interconnect structure at least partially overlapping with the capacitor.

The bulk acoustic wave resonator structure can include a second capacitor in series with the bulk acoustic wave resonator. The second capacitor can include a second capacitor portion of one of the first electrode or the second electrode. The second capacitor can be non-overlapping with the acoustic reflector.

Another aspect of this disclosure is an acoustic wave filter for filtering a radio frequency signal. The acoustic wave filter includes a bulk acoustic wave resonator including an acoustic reflector, a first electrode, a second electrode, a piezoelectric layer positioned between the first electrode and the second electrode, and a frame structure; a metal-insulator-metal capacitor in parallel with the bulk acoustic wave resonator, the metal-insulator-metal capacitor including a portion of the first electrode and a portion of the second electrode, and at least part of the metal-insulator-metal capacitor is positioned laterally relative to the acoustic reflector; and a plurality of additional acoustic wave resonators, the bulk acoustic wave resonator and the plurality of additional acoustic wave resonators configured to filter the radio frequency signal.

The acoustic wave filter can include a second metal-insulator-metal capacitor in series with the bulk acoustic wave resonator. The bulk acoustic wave resonator, the metal-insulator-metal capacitor, and second metal-insulator-metal capacitor can be over a common substrate.

The radio frequency signal can be a New Radio signal.

Another aspect of this disclosure is a bulk acoustic wave resonator structure that includes a bulk acoustic wave resonator and a metal-insulator-metal capacitor. The bulk acoustic wave resonator includes an acoustic reflector, a first electrode, a second electrode, a piezoelectric layer positioned between the first electrode and the second electrode, and a frame structure. The metal-insulator-metal capacitor includes a portion of the first electrode and an engineered region of the piezoelectric layer. The engineered region of the piezoelectric layer has a lower magnitude effective piezoelectric coefficient than the piezoelectric layer in an acoustically active region of the bulk acoustic wave device. At least part of the metal-insulator-metal capacitor is positioned laterally relative to the acoustic reflector. The frame structure at least partly overlaps with engineered region of the piezoelectric layer.

Another aspect of this disclosure is a bulk acoustic wave resonator structure that includes a bulk acoustic wave resonator and a metal-insulator-metal capacitor. The bulk acoustic wave resonator has an active region and an engineered region. The bulk acoustic wave resonator includes a first electrode, a second electrode, and a piezoelectric layer positioned between the first electrode and the second electrode in at least the active region. The piezoelectric layer has a lower magnitude effective piezoelectric coefficient in the engineered region than in the active region. The metal-insulator-metal capacitor includes a portion of the first electrode and at least a portion of the piezoelectric layer in the engineered region.

The bulk acoustic wave resonator and the metal-insulator-metal capacitor can be electrically coupled in series. The bulk acoustic wave resonator and the metal-insulator-metal capacitor can be over a common substrate. The bulk acoustic wave resonator can include an air cavity between the common substrate and the piezoelectric layer in the active region, where the air cavity does not extend between the metal-insulator-metal capacitor and the common substrate. The portion of the piezoelectric layer in the engineered region of the metal-insulator-metal capacitor can be positioned closer to the common substrate than the piezoelectric layer in the active region.

The bulk acoustic wave resonator can include a frame structure at least partially overlapping with the engineered region.

The metal-insulator-metal capacitor further can include a conductive layer. The metal-insulator-metal capacitor can include a raised frame structure. The metal-insulator-metal capacitor can include at least a portion of an interconnect structure.

The bulk acoustic wave resonator structure can include a support substrate and an acoustic reflector positioned between the support substrate and the first electrode. The acoustic reflector can include a cavity. The bulk acoustic wave resonator structure can include a pillar in the cavity, where the pillar is positioned laterally between the bulk acoustic wave resonator and the metal-insulator-metal capacitor.

Another aspect of this disclosure is a bulk acoustic wave resonator structure that includes a bulk acoustic wave resonator and a capacitor. The bulk acoustic wave resonator includes a resonator portion of a first electrode, a resonator portion of a second electrode, and a piezoelectric layer positioned between the resonator portion of the first electrode and the resonator portion of the second electrode. The capacitor includes a capacitor portion of the second electrode, a conductive layer, and an insulator positioned between the capacitor portion of the second electrode and the conductive layer.

The bulk acoustic wave resonator and the capacitor can be electrically coupled in series. The bulk acoustic wave resonator further can include a frame structure. The capacitor can include a raised frame structure.

The bulk acoustic wave resonator structure can include an interconnect structure at least partially over the capacitor.

The bulk acoustic wave resonator structure can include a support substrate and an acoustic reflector positioned between the support substrate and the first electrode. The acoustic reflector can include a cavity. The bulk acoustic wave resonator structure can include a pillar in the cavity, where the pillar is positioned laterally between the resonator and the metal-insulator-metal capacitor. The cavity can be at least partially filled with a filler material.

Another aspect of this disclosure is an acoustic wave filter for filtering a radio frequency signal. The acoustic wave filter includes a bulk acoustic wave resonator and a capacitor in accordance with any suitable principles and advantages disclosed herein and a plurality of additional acoustic wave resonators. The bulk acoustic wave resonator and the plurality of additional acoustic wave resonators are configured to filter the radio frequency signal.

Another aspect of this disclosure is a multiplexer for filtering radio frequency signals. The multiplexer includes a first filter including a bulk acoustic wave resonator and a capacitor in accordance with any suitable principles and advantages disclosed herein, and a second filter coupled to the first filter at a common node.

Another aspect of this disclosure is a radio frequency module that includes a filter including a bulk acoustic wave resonator and a capacitor in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave resonator and a capacitor in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave resonator and a capacitor in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes a bulk acoustic wave resonator and a capacitor in accordance with any suitable principles and advantages disclosed herein.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a bulk acoustic wave (BAW) resonator structure with an integrated capacitor according to an embodiment.

FIGS. 1B-1 and 1B-2 are graphs showing quality factor (Qs or Qp) ranges of the BAW resonator structure of FIG. 1A with different lengths of a capacitor portion of a first electrode in the BAW resonator of FIG. 1A.

FIG. 1B-3 is a graph showing coupling coefficient kt² ranges of the BAW resonator structure of FIG. 1A with different lengths of the capacitor portion of the first electrode.

FIGS. 2, 3, 4, 5, 6, 7, 8A, and 8B are schematic cross-sectional side views of BAW resonator structures with integrated capacitors according to various embodiments.

FIG. 9A is an example schematic top plan view of a capacitor integrated BAW device. FIG. 9B is another example schematic top plan view of a capacitor integrated BAW device.

FIG. 10 is an example of a BAW solidly mounted resonator (SMR) with an integrated capacitor according to an embodiment.

FIG. 11 is an example of a BAW SMR with an integrated capacitor according to another embodiment.

FIG. 12A is a schematic diagram of a ladder filter that includes one or more BAW resonator structures according to an embodiment.

FIG. 12B is schematic diagram of a band pass filter.

FIGS. 13A, 13B, 13C, and 13D are schematic diagrams of multiplexers that include a filter with one or more BAW resonators according to an embodiment.

FIGS. 14, 15, and 16 are schematic block diagrams of modules that include a filter with one or more BAW resonators according to an embodiment.

FIG. 17 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other.

Acoustic wave filters can filter radio frequency (RF) signals in a variety of applications, such as in an RF front end of a mobile phone. An acoustic wave filter can be implemented with bulk acoustic wave (BAW) devices. A film acoustic wave resonator (FBAR) and a BAW solidly mounted resonator (SMR) are examples of BAW devices. A bandwidth of a filter is defined as the range of frequencies over which the device can effectively filter signals. A larger effective electromechanical coupling coefficient or coupling factor (kt²) can contribute to providing a wider bandwidth with a BAW device. However, when a relatively large kt² BAW resonator is used in a filter, the skirt performance and/or the insertion loss of the filter can be degraded.

A capacitor can provide additional capacitance in parallel or in series with a BAW resonator of a filter. Capacitors can be used for various purposes in filters and/or other electronic circuits, such as tuning the resonant frequency or providing impedance matching. The capacitors can be coupled with BAW resonators to achieve desired electrical characteristics. For example, a capacitor in parallel with a BAW resonator of a filter can improve the skirt performance and the insertion loss of the filter. In some applications, such a capacitor is provided separately from the BAW resonator. The separately provided capacitor can introduce, for example, losses in the filter.

Increasing the quality factor (Q) of a given BAW resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices disclosed herein can achieve improved performance by engineering a region of a piezoelectric layer. Part of the engineered region of the piezoelectric layer can be included as a dielectric of a capacitor in embodiments of this disclosure.

BAW devices can include frame structures. A frame structure is a structure that adjusts mass loading in a portion of a BAW device over an acoustic reflector. A frame structure can include a raised frame structure that adds mass loading and/or a recessed frame structure that reduces mass loading. A raised frame structure can include an additional layer and/or a thicker portion of material that increases mass loading in a portion of a BAW device relative to a main acoustically active region. In some applications, a raised frame layer can include a different material than layers in contact with the raised frame layer. In some applications, a raised frame layer can include a same material as a layer in contact with the raised frame layer. A raised frame structure can be a multi-layer structure that includes two or more raised frame layers. A recessed frame structure can include a thinner portion of a layer of a BAW device that decreases mass loading in a portion of the BAW device relative to a main acoustically active region. Certain BAW devices include a frame structure around the main acoustically active region of the BAW device. Such a frame structure can be included around a periphery of the BAW device. In certain applications, the frame structure can surround the main acoustically active region in plan view. In some other applications, the frame structure can be around some but not all of the main acoustically active region in plan view.

A BAW device can include a first electrode, a second electrode, and a piezoelectric layer positioned between the first and second electrodes. A frame structure, such as a raised frame and/or a recessed frame, can be positioned around a main acoustically active region of the BAW device to reduce lateral energy leakage from the main acoustically active region. A region of the BAW device that includes the frame structure can be referred to as a frame region. A raised frame structure can create a resonance at a frequency that is below a resonant frequency of the main acoustically active region of the BAW device. This resonance can be below a main resonant frequency of the BAW device. A resonance associated with the raised frame structure can be referred to as a raised frame mode. The raised frame mode can be undesirable in certain applications.

Various embodiments disclosed herein relate to resonator structures (e.g., BAW resonator structures) that include a capacitor. The resonator structures can seamlessly integrate a capacitor and a resonator and be referred to as capacitor integrated resonators or resonators with one or more integrated capacitors. A BAW resonator structure according to some embodiments can include a BAW resonator and a capacitor. The capacitor can be a conductor-insulator-conductor (e.g., metal-insulator-metal) capacitor. The BAW resonator and the capacitor can be electrically coupled. In some embodiments, the BAW resonator and the capacitor can be electrically coupled in parallel with each other. The BAW resonator can include an acoustic reflector, a first electrode, a second electrode, and a piezoelectric layer positioned between the first electrode and the second electrode. The capacitor can include a portion of the first electrode and a portion of the second electrode. Portions of the first and second electrodes that are in the acoustically active region can be referred to as resonator portions of the first and second electrodes, and the portions of the first electrode and the second electrode that are part of the capacitor can be referred to as capacitor portions of the first and second electrodes. The capacitor portions of the first electrode and the second electrode can extend laterally beyond the acoustic reflector (e.g., air cavity) of the bulk acoustic wave resonator. The capacitor can include the capacitor portions of the first and second electrodes and an insulator between the capacitor portions of the capacitor portions of the first and second electrodes. The insulator can include an engineered piezoelectric layer. In some embodiments, the piezoelectric layer and the engineered piezoelectric layer can be portions of a single layer.

The capacitor integrated BAW resonator can include a frame structure (e.g., a raised frame structure and/or a recessed raised frame structure) and the insulator can be positioned in a frame region in which the frame structure is positioned. The insulator (e.g., the engineered piezoelectric layer) can suppress a frame mode associated with the frame structure.

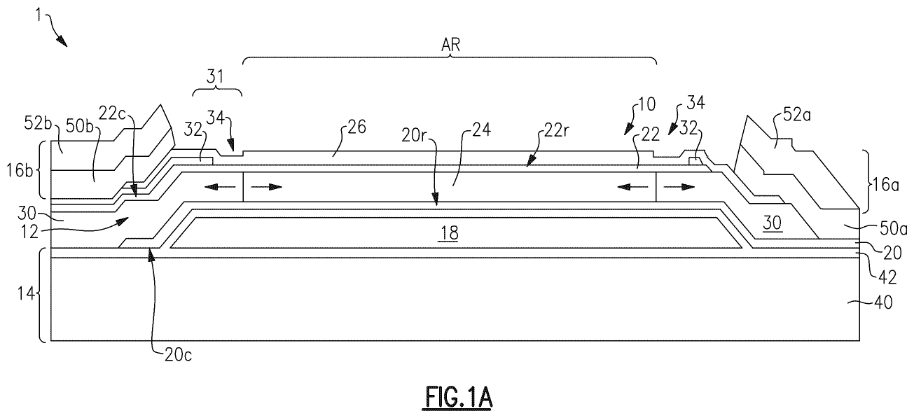

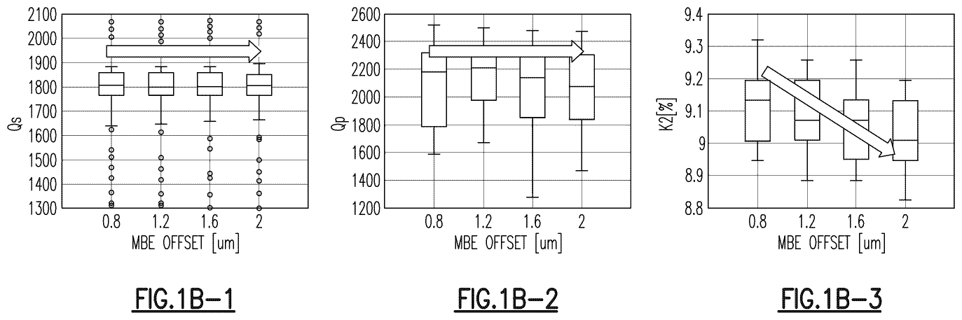

FIG. 1A is a schematic cross-sectional side view of a bulk acoustic wave (BAW) resonator structure 1 with an integrated capacitor 12 according to an embodiment. The BAW resonator structure 1 can also be referred to as a capacitor integrated BAW resonator or a BAW resonator structure. The capacitor integrated BAW resonator structure 1 can include a resonator 10 (e.g., a BAW resonator), a capacitor 12 (e.g., a metal-insulator-metal capacitor), a support structure 14, first and second interconnect structures 16a, 16b, and a cavity 18.

The resonator 10 can include a first electrode 20, a second electrode 22, and a piezoelectric layer 24. The first electrode 20 can include a resonator portion 20r and a capacitor portion 20c, and the second electrode 22 can include a resonator portion 22r and a capacitor portion 22c. The resonator portion 20r of the first electrode 20, the resonator portion 22r of the second electrode 22, and the piezoelectric layer 24 overlap in an acoustically active region AR of the capacitor integrated BAW resonator 1. A passivation layer 26 can be provided over the second electrode 22.

The first electrode 20 can be referred to as a lower electrode. The first electrode 20 can have a relatively high acoustic impedance. The first electrode 20 can include molybdenum (Mo), tungsten (W), ruthenium (Ru), chromium (Cr), iridium (Ir), platinum (Pt), or any suitable alloy and/or combination thereof. Similarly, the second electrode 22 can have a relatively high acoustic impedance. The second electrode 22 can include Mo, W, Ru, Cr, Ir, Pt, or any suitable alloy and/or combination thereof. The second electrode 22 can be formed of the same material as the first electrode 20 in certain applications. The second electrode 22 can be referred to as an upper electrode. The thickness of the first electrode 20 can be approximately the same as the thickness of the second electrode 22 in the acoustically active region AR of the capacitor integrated BAW resonator 1.

The piezoelectric layer 24 can include a suitable material such as, but not limited to, aluminum nitride (AlN), zinc oxide (ZnO), or lead zirconium titanate (PZT). In certain applications, the piezoelectric layer 24 can be an AlN layer. The piezoelectric material can be doped or undoped. For example, an AlN-based piezoelectric layer can be doped with any suitable dopant, such as scandium (Sc), chromium (Cr), magnesium (Mg), sulfur (S), yttrium (Y), silicon (Si), germanium (Ge), oxygen (O), hafnium (Hf), zirconium (Zr), titanium (Ti), or the like. In certain applications, the piezoelectric layer 24 can be AlN based layer doped with Sc. Doping the piezoelectric layer 24 can adjust the resonant frequency. Doping the piezoelectric layer 24 can increase the electromechanical coupling coefficient (kt²) of the capacitor integrated BAW device 1. Doping to increase the kt² can be advantageous at higher frequencies where kt² can be degraded. In certain applications, two or more piezoelectric layers can be implemented with any suitable principles and advantages disclosed herein. The stacked piezoelectric layers can have c-axes oriented in opposite directions in the acoustically active region and excite an overtone mode as a main mode of a BAW resonator.

The capacitor 12 can be defined by a portion of the BAW resonator structure 1 where the first electrode 20, the second electrode 22, and the insulator 30 overlap. The capacitor 12 can include a capacitor portion 20c of the first electrode 20, a capacitor portion 22c of the second electrode 22, and an insulator 30 between the capacitor portion 20c of the first electrode 20 the capacitor portion 22c of the second electrode 22. The capacitor portions 20c and 22c can both extend beyond the cavity 18. The capacitor 12 can be a metal-insulator-metal capacitor. As illustrated in FIG. 1A, the resonator 10 and the capacitor 12 can be electrically coupled in parallel. The capacitor 12 can be at least partly laterally offset from the cavity 18 or the resonator 10. In the illustrated embodiment, an end of the first electrode 20 extends away from the acoustically active region AR on a side of the resonator 10 where the second electrode 22 is connected to the first and second interconnect structures 16a, 16b. The insulator 30 can be in a peripheral region of the capacitor integrated BAW resonator structure 1 that at least partially surrounds the acoustically active region AR. In some embodiments, a length of the capacitor portion 20c of the first electrode 20 can be selected or adjusted to control the capacitance value of the capacitor 12. With more overlap of the first capacitor 20 and the second electrode 22, the capacitor 12 has a larger area and, consequently, a larger capacitance. In some embodiments, the capacitor 12 can at least partially overlap a frame structure 31. The frame structure 31 can include a raised frame structure 32 and/or a recessed frame structure 34. In some embodiments, the capacitor 12 can at least partially overlap with the second interconnect structure 16b and be at least partially positioned between the support structure 14 and the second interconnect structure 16b.

Because the capacitor 12 is integrated with the resonator 10 in the capacitor integrated BAW resonator 1, the resonator 10 and the capacitor 12 can be seamlessly coupled. Compared to coupling an external capacitor, loss can be reduced in the capacitor integrated BAW resonator structure 1 and a total size of the capacitor and the resonator can be reduced. In some embodiments, the capacitor 12 can at least partially surround the acoustically active region AR in a plan view. For example, the capacitor 12 can fully surround the acoustically active region AR in the plan view in certain applications.

The insulator 30 can include any suitable dielectric material. In some embodiments, the insulator 30 can be an engineered region of a piezoelectric layer. The engineered region of the piezoelectric layer can have a lower magnitude effective piezoelectric coefficient than the piezoelectric layer 24 in the active region AR. For example, a magnitude of the effective piezoelectric coefficient of the engineered region of the piezoelectric layer can be less than 50% of a magnitude of the effective piezoelectric coefficient of the piezoelectric layer 24 in the acoustically active region AR. As another example, a magnitude of the effective piezoelectric coefficient of the engineered region of the piezoelectric layer can be less than 20% of a magnitude of the effective piezoelectric coefficient of the piezoelectric layer 24 in the acoustically active region AR. As one more example, a magnitude of the effective piezoelectric coefficient of the engineered region of the piezoelectric layer can be less than 10% of a magnitude of the effective piezoelectric coefficient of the piezoelectric layer 24 in the acoustically active region AR.

The effective piezoelectric coefficient can be an aggregate piezoelectric coefficient for the entire engineered region 24e. The aggregate magnitude of the piezoelectric polarization vectors in the engineered region 24e should be less than the magnitude in the regular region 24r. The lower magnitude effective piezoelectric coefficient can be a result of the non-aligned nature of piezoelectric material crystal orientations within the engineered region 24e causing a lower aggregate magnitude of the piezoelectric polarization vectors.

The effective piezoelectric coefficient can be an effective piezoelectric coupling coefficient (e₃₃), for example. The engineered region 24e of the piezoelectric layer 24 can suppress the frame mode associated with the raised frame structure 32. BAW devices with an engineered region of a piezoelectric layer and a frame structure (e.g., a raised frame structure 32 and/or a recessed frame structure 34) disclosed herein can enable frame mode suppression, transverse mode suppression, and lateral mode suppression

As an example, the insulator 30 and the piezoelectric layer 24 can be formed from a single layer and the insulator 30 can be an engineered region of the single layer. In some embodiments, a uniform piezoelectric material can be deposited and then the engineered region of the piezoelectric material can be modified to be less piezoelectric than the acoustically active region AR to form the piezoelectric layer 24 and the insulator 30. For example, ions can be implanted to modify the structure and properties of the piezoelectric material by ion implantation to form the insulator 30. In such embodiments, the piezoelectric material can be engineered from a side opposite the first electrode 20. In some embodiments, the piezoelectric material can be deposited over different materials in a peripheral region of the capacitor integrated BAW resonator structure 1 and in the acoustically active region AR. For example, a seed layer (not illustrated in FIG. 1A) can be provided over the first electrode 20 in the peripheral region and the first electrode 20 can be free from the seed layer in the acoustically active region AR. Depositing the piezoelectric material over the seed layer in the peripheral region can cause the piezoelectric material to have a different structure and different properties in the peripheral region than in the acoustically active region AR. In these embodiments, the piezoelectric material can be engineered from a side of the first electrode 20 to form the insulator 30.

The arrows at intersections between the piezoelectric layer 24 and the insulator 30 in FIG. 1A indicate that the intersections can be shifted or selected for particular applications. The capacitance of the capacitor 12 can be increased by shifting at least one intersection to increase the portion of the BAW resonator structure 1 where the first electrode 20, the second electrode 22, and the insulator 30 overlap. Similarly, the capacitance of the capacitor 12 can be decreased by shifting at least one intersection to decrease the portion of the BAW resonator structure 1 where the first electrode 20, the second electrode 22, and the insulator 30 overlap. Shifting the intersection between the piezoelectric layer 24 and the insulator 30 can impact frame mode suppression.

The frame structure 31 can be configured to suppress the transverse mode. The raised frame structure 32 can reduce or impede propagation of transverse mode. The raised frame structure 32 can include a material that has a relatively high mass density. For instance, the raised frame structure 32 can include molybdenum (Mo), tungsten (W), ruthenium (Ru), the like, or any suitable alloy thereof. In some embodiments, the raised frame structure 32 and the second electrode 22 can be formed of a same material. The raised frame structure 32 can be a metal layer. Alternatively, the raised frame structure 32 can be a suitable non-metal material with a relatively high density. The density of the raised frame structure 32 can be similar to or heavier than the density of the first electrode 20 or the second electrode 22. The raised frame structure 32 can include a relatively low acoustic impedance material that has a lower acoustic impedance than the first electrode 20, the second electrode 22, and/or the piezoelectric layer 24. For example, the raised frame structure 32 can include a silicon dioxide (SiO₂) layer, a silicon nitride (SiN) layer, a silicon carbide (SiC) layer, or any other suitable low acoustic impedance layer. The raised frame structure 32 can be a dielectric layer. The raised frame structure 32 can be an oxide layer.

The frame structure 31 can include, for example, a single layer raised frame structure as the raised frame structure 32, a multi-layer raised frame structure that includes two or more raised frame layers, or a combination of a raised frame structure 32 and a recessed frame structure 34. As an example, a frame structure can have a multi-layer raised frame structure that includes a relatively high density layer and a relatively low acoustic impedance layer. The low acoustic impedance layer can contribute to reducing an effective electromechanical coupling coefficient (kt²) relative to a single high-density raised frame structure, which can reduce excitation strength of a raised frame spurious mode. As another example, a floating raised frame structure can be implemented. In the capacitor integrated BAW resonator 1, the frame structure 31 is illustrated as being asymmetric about the acoustically active region AR. However, in some embodiments, the frame structure 31 can be symmetric about the acoustically active region AR.

In the capacitor integrated BAW resonator 1, the insulator 30 is positioned vertically relative to the frame structure 31. With the insulator 30 between the first electrode 20 and the second electrode 22 under the frame structure 31, there can be little or no resonance associated with the frame structure 31 in the capacitor integrated BAW resonator 1. A reduced magnitude of the effective piezoelectric coupling coefficient in the insulator 30 (e.g., the engineered region of the piezoelectric layer) can increase Q of the capacitor integrated BAW resonator structure 1 and/or attenuate one or more spurs, such a spur associated with one or more frame modes.

The support structure 14 can include a support substrate 40 and an intermediate layer 42 between the support substrate and the first electrode 20. The support substrate 40 can be a semiconductor substrate. The support substrate 40 can be a silicon substrate. The support substrate 40 can be any other suitable support substrate, such as a substrate of quartz, silicon carbide, sapphire, glass, gallium arsenide, or any suitable ceramic (e.g., spinel, alumina, etc.).

The intermediate layer 42 can include, for example, one or more of a seed layer, a trap rich layer, a passivation layer, or any other suitable functional layers. In some embodiments, the intermediate layer 42 can be completely or partially omitted. In such embodiments, the capacitor portion 20c of the first electrode 20 can directly contact the support substrate 40. The intermediate layer 42 can be relatively thin. For example, the intermediate layer 42 can be significantly thinner than the support substrate 40. Heat generated by the resonator 10 can dissipate through the first electrode 20 to the support substrate 40 at a location where there is no cavity 18 between the first electrode 20 and the support substrate 40. In some embodiments, the intermediate layer 42 can include silicon nitride, silicon carbide, aluminum nitride, or similar materials.

The first interconnect structure 16a can include one or more conductive layers such as a first conductive layer 50a and a second conductive layer 52a. Similarly, the second interconnect structure 16b can include one or more conductive layers such as a first conductive layer 50b and a second conductive layer 52b. The first conductive layers 50a, 50b and the second conductive layers 52a, 52b can each include a material suitable for interconnecting the capacitor integrated BAW resonator structure 1 and one or more other component (e.g., another resonator) in a filter, an external component, or a ground connection. The first conductive layers 50a, 50b and/or the second conductive layers 52a, 52b can be highly conductive. For example, the first conductive layers 50a, 50b and/or the second conductive layers 52a, 52b can be more electrically conductive than the first electrode 20 and/or the second electrode 22. In some embodiments, the first conductive layers 50a, 50b and/or the second conductive layers 52a, 52b can include one or more of gold (Au), titanium (Ti), copper (Cu), aluminum (Al), or tungsten (W).

The cavity 18 (e.g., an air cavity) can be formed between the support substrate 40 and the first electrode 20. The cavity 22 is an example of an acoustic reflector. The capacitor integrated BAW resonator structure 1 can include a film bulk acoustic wave resonator (FBAR). In some other embodiments, there can be a solid acoustic mirror in place of the cavity 18 and such a BAW device can be a BAW solidly mounted resonator (SMR).

The capacitor integrated BAW resonator structure 1 can integrate the capacitor 12 without significantly degrading the quality factor as compared to a BAW resonator that does not integrate a capacitor.

FIG. 1B-1 is a graph showing quality factor (Qs) ranges for the BAW resonator of the capacitor integrated BAW resonator structure 1 simulated with different lengths of the capacitor portion 20c of the first electrode 20. FIG. 1Bf-2 is a graph showing quality factor (Qp) ranges for the BAW resonator of the capacitor integrated BAW resonator structure 1 simulated with different lengths of the capacitor portion 20c of the first electrode 20. FIG. 1Bf-3 is a graph showing coupling coefficient kt² ranges for the BAW resonator of the capacitor integrated BAW resonator structure 1 at different lengths of the capacitor portion 20c of the first electrode 20. FIGS. 1B-1 to 1Bf-2 indicate that the quality factor (Qs and Qp) is maintained at relatively high value even when the length of the capacitor portion 20c increases. Including an engineered piezoelectric layer under the frame structure of the BAW resonator can contribute to achieving these quality factor values. FIG. 1Bf-3 indicates that the electromechanical coupling coefficient kt² can have a lower value when the length of the capacitor portion 20c is larger.

In the capacitor integrated BAW resonator structure 1 shown in FIG. 1A, the first electrode 20 and the second electrode 22 overlap beyond the cavity 18 at one side of the capacitor integrated BAW resonator 1. However, in some other embodiments, the first electrode 20 and the second electrode 22 can overlap on opposing sides of the acoustically active region AR beyond the acoustic reflector in increase capacitance of a capacitor in parallel with a BAW resonator.

The capacitor integrated bulk acoustic wave (BAW) resonator structure 1 utilizes both the first and second electrodes 20 and 22, respectively, to form the capacitor 12. However, one or more additional conductive layers can be provided in a capacitor integrated BAW resonator. For example, at least a portion of the raised frame structure 32 and/or at least a portion of the second interconnect structure 16b can be part of the capacitor.

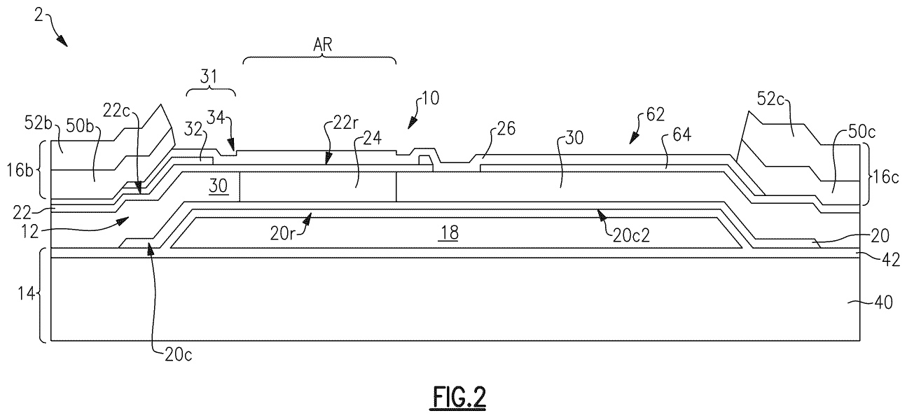

In certain embodiments, a metal-insulator-metal capacitor can be electrically connected to a BAW resonator and formed over an acoustic reflector, such as an air cavity. Such a metal-insulator-metal capacitor can include a portion of an electrode of the BAW resonator and an engineered piezoelectric layer. The metal-insulator-metal capacitor can be connected in series with the BAW resonator. Examples of metal-insulator-metal capacitors are described with reference to FIGS. 2-6. In some instances, a common air cavity can extend under the metal-insulator-metal capacitor and the piezoelectric and electrode stack of the BAW resonator. A pillar can be formed in the air cavity in certain applications.

FIG. 2 is a schematic cross-sectional side view of a capacitor integrated bulk acoustic wave (BAW) resonator structure 2 according to an embodiment. Unless otherwise noted, the components of the capacitor integrated BAW resonator structure 2 shown in FIG. 2 may be structurally and/or functionally the same as or generally similar to like components of other BAW devices disclosed herein. The capacitor integrated BAW resonator structure 2 can include a resonator 10, a capacitor 12 coupled in parallel with the resonator 10, and a capacitor 62 coupled in series with the resonator 10. The capacitor 62 of the capacitor integrated BAW resonator structure 2 includes a conductive layer 64 separate from the first and second electrodes 20 and 22, respectively. In the capacitor integrated BAW resonator structure 2, a common cavity 18 extends under the capacitor 62 and the electrode and piezoelectric stack of the resonator 10.

The capacitor 62 can include a second capacitor portion 20c2 of the first electrode 20, the conductive layer 64, and an insulator 30 between the second capacitor portion 20c2 and the conductive layer 64. As described with respect to FIG. 1A, the insulator 30 can include any suitable dielectric material. In some embodiments, the insulator 30 can include an engineered region of the piezoelectric layer. For example, the insulator 30 and the piezoelectric layer 24 can be formed from a single layer and the insulator 30 can be an engineered region of the single layer. The passivation layer 26 can at least partially cover the conductive layer 64. An area where the second capacitor portion 20c2 of the first electrode 20 and the conductive layer 64 overlap can define the capacitor 62. A size of the area where the second capacitor portion 20c2 of the first electrode 20 and the conductive layer 64 overlap impact the capacitance value of the capacitor 62. In some embodiments, the conductive layer 64 can be connected to ground through an interconnect structure 16c, which can include a first conductive layer 50c and a second conductive layer 52c.

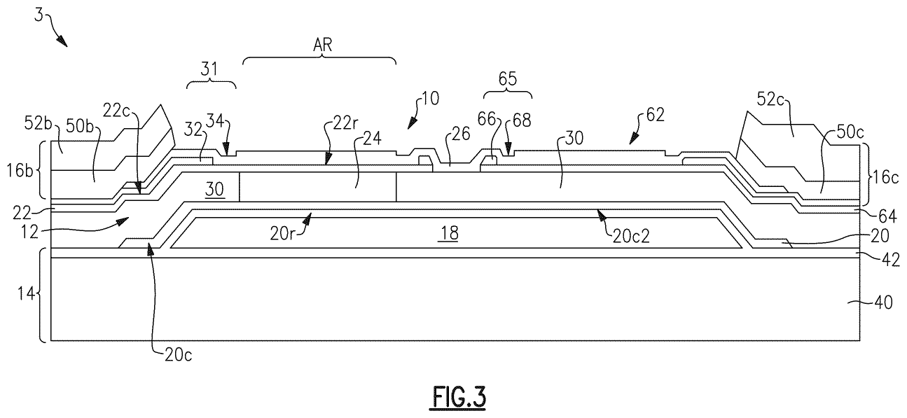

The length of the capacitor portion 20c of the first electrode 20 that overlaps the capacitor portion 22c of the second electrode 22 can be selected to control the capacitance of the capacitor 12. In some embodiments, the capacitor 12 can be omitted and the capacitor 62 may be the only capacitor included in a capacitor integrated BAW resonator. In some embodiments, the capacitor 62 can also include a frame structure like in the resonator 10. An example of such embodiments is illustrated in FIG. 3.

FIG. 3 is a schematic cross-sectional side view of a capacitor integrated bulk acoustic wave (BAW) resonator structure 3 according to an embodiment. Unless otherwise noted, the components of the capacitor integrated BAW resonator structure 3 shown in FIG. 3 may be structurally and/or functionally the same as or generally similar to like components of other BAW devices disclosed herein. The capacitor integrated BAW resonator structure 3 can be generally similar to the capacitor integrated BAW resonator structure 2 of FIG. 2, except that the capacitor 62 in the capacitor integrated BAW resonator structure 3 includes a frame structure 65.

The frame structure 65 can include a raised frame structure 66 and the recessed frame structure 68. In some embodiments, the conductive layer 64, the raised frame structure 66, and the recessed frame structure 68 can be generally symmetric with the second electrode 22, the raised frame structure 32, and the recessed frame structure 34 of the resonator 10.

FIG. 4 is a schematic cross-sectional side view of a capacitor integrated bulk acoustic wave (BAW) resonator structure 4 according to an embodiment. Unless otherwise noted, the components of the capacitor integrated BAW resonator structure 4 shown in FIG. 4 may be structurally and/or functionally the same as or generally similar to like components of other BAW devices disclosed herein. The capacitor integrated BAW resonator structure 4 can be generally similar to the capacitor integrated BAW resonator structure 3 of FIG. 3, except that the first electrode 20 terminates over the cavity 18. In the capacitor integrated BAW resonator structure 4, the cavity 18 extends beyond the first electrode 20 on opposing sides of the cross-sectional view shown in FIG. 4. In some embodiments, an end of the first electrode 20 associated with the resonator 10 can extend closer or farther from an edge of the cavity 18 than an end of the first electrode 20 associated with to the capacitor 62. In some embodiments, the first electrode 20 does not extend beyond the cavity 18 on one side of the resonator 10 and extends beyond the cavity 18 on an opposing side of the resonator 10.

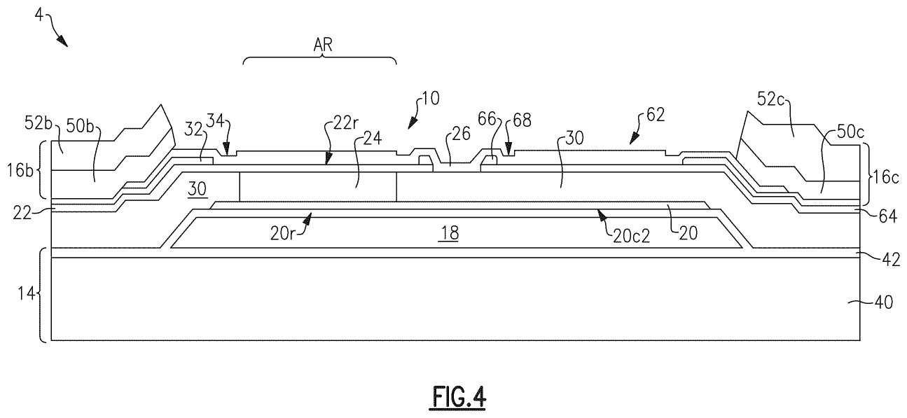

FIG. 5 is a schematic cross-sectional side view of a capacitor integrated bulk acoustic wave (BAW) resonator structure 5 according to an embodiment. Unless otherwise noted, the components of the capacitor integrated BAW resonator structure 5 shown in FIG. 5 may be structurally and/or functionally the same as or generally similar to like components of other BAW devices disclosed herein. The capacitor integrated BAW resonator structure 5 can be generally similar to the capacitor integrated BAW resonator structure 2 of FIG. 2, except that the capacitor integrated BAW resonator structure 5 further includes a pillar 70 between the first electrode 20 and the support structure 14. The pillar 70 can be positioned laterally between the resonator 10 and the capacitor 62. The pillar 70 can include any suitable dielectric material, metal, or piezoelectric material. The pillar 70 can provide structural support. The pillar 70 can provide a thermal path for heat dissipation.

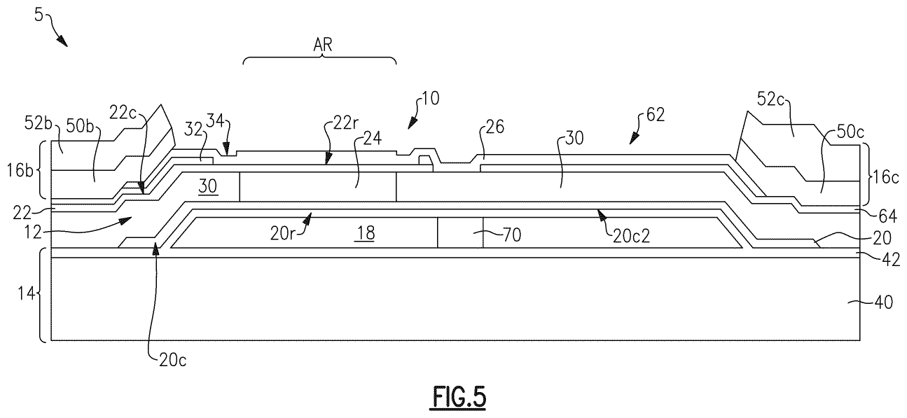

FIG. 6 is a schematic cross-sectional side view of a capacitor integrated bulk acoustic wave (BAW) resonator structure 6 according to an embodiment. Unless otherwise noted, the components of the capacitor integrated BAW resonator structure 6 shown in FIG. 6 may be structurally and/or functionally the same as or generally similar to like components of other BAW devices disclosed herein. The capacitor integrated BAW resonator structure 6 can be generally similar to the capacitor integrated BAW resonator structure 5 of FIG. 5, except that the first and second conductive layers 50c, 52c of the interconnect structure 16c in the capacitor integrated BAW resonator structure 6 extend over the conductive layer 64. The passivation layer 26 can be omitted from between the first conductive layer 50 and the second electrode 64. In some embodiments, the capacitor 12 with the first and second conductive layers 50, 52 that are positioned over the capacitor 12 can have lower resistance and lower losses.

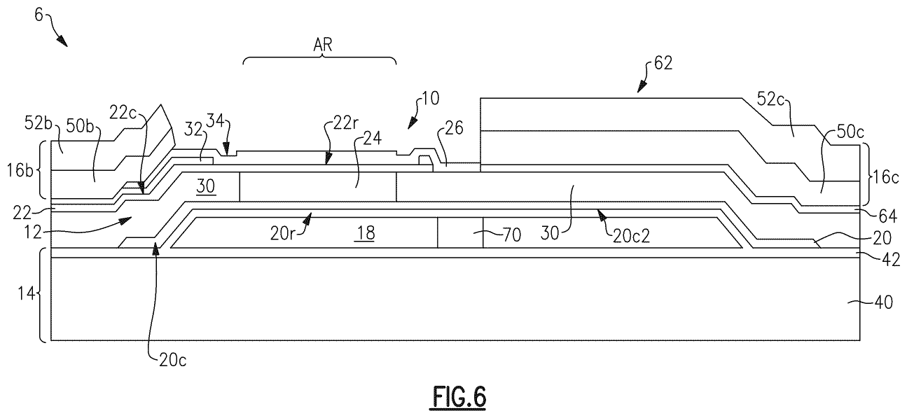

FIG. 7 is a schematic cross-sectional side view of a capacitor integrated bulk acoustic wave (BAW) resonator structure 7 according to an embodiment. Unless otherwise noted, the components of the capacitor integrated BAW resonator structure 7 shown in FIG. 7 may be structurally and/or functionally the same as or generally similar to like components of other BAW devices disclosed herein. The capacitor integrated BAW resonator structure 7 can be generally similar to the capacitor integrated BAW resonator structure 6 of FIG. 6, except that the cavity 18 of the capacitor integrated BAW resonator structure 6 is partially filled with a filler 74. In some embodiments, a filler 74 that includes a dielectric material or a metal is included under the capacitor portion 20c2 of the first electrode 20. When the cavity 18 under the capacitor 62 is filled with a metal, it can be preferred to at least partially remove the intermediate layer 42 between the first electrode 20 and the filler 74 for an improved heat path and increased quality factor for the capacitor 62. For example, the cavity 18 can be formed under the resonator 10 without removing the filler 74 from under the capacitor 62 during release. In some embodiments, there may be no cavity 18 or filler 74 between the capacitor 62 and the support structure 14.

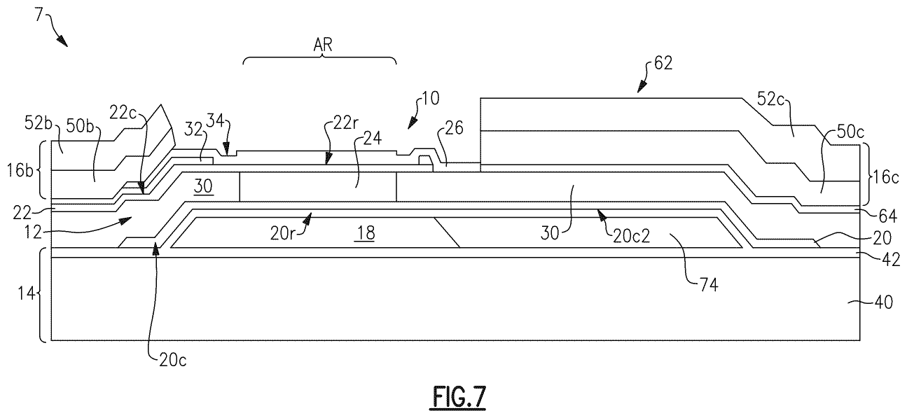

FIG. 8A is a schematic cross-sectional side view of a capacitor integrated BAW resonator structure 8 according to an embodiment. FIG. 8B is a schematic cross-sectional side view of a capacitor integrated BAW resonator structure 8′ according to an embodiment. Unless otherwise noted, the components of the capacitor integrated BAW resonator structures 8, 8′ shown in FIGS. 8A and 8B may be structurally and/or functionally the same as or generally similar to like components of other BAW devices disclosed herein. The capacitor integrated BAW resonator structure 8 can be generally similar to the capacitor integrated BAW resonator structure 7 of FIG. 7. FIG. 8A shows that the distance between the support structure 14 and the first electrode 20 can be different under the resonator structure 10 than under the capacitor 62. For example, the distance between the support structure 14 and the first electrode 20 is less under the capacitor 62 in FIG. 8A than under the resonator 10. In some embodiments, there may be no cavity 18 and no filler material 74 between the first electrode 20 and the support structure 14 under the capacitor 62, for example, as shown in FIG. 8B. In some other embodiments, the distance between the first electrode 20 and the support structure 10 can be greater under the capacitor 62 than under the resonator 10.

Any suitable combination of the features from two or more of FIGS. 1A-8B can be implemented in a bulk acoustic wave (BAW) device. For example, a capacitor integrated BAW resonator can include a parallel capacitor and/or a series capacitor coupled to a resonator. When an insulating layer (e.g., engineered piezoelectric layer) overlaps a frame structure (e.g., the frame structure 31), a frame mode can be suppressed. The insulating layer can also form the insulator of a metal-insulator-metal capacitor that is integrated with the BAW device.

The illustrated embodiments of FIGS. 2-8B show a capacitor 62 that includes a portion of the first electrode 20 and the conductive layer 64. In some other embodiments, a similar capacitor can be implemented by a conductive layer and a portion of the second electrode 22. For instance, in such embodiments, the first electrode 20 can terminate at or near an edge of the acoustically active region AR, a conductive layer 64 can be between the insulator 30 and an acoustic reflector (e.g., air cavity such as the cavity 18), and the second electrode 22 can extend further such that a metal-insulator-meal capacitor includes a portion of the second electrode 22, the conductive layer 64, and the insulator 30 between the second electrode 22 and the conductive layer 64.

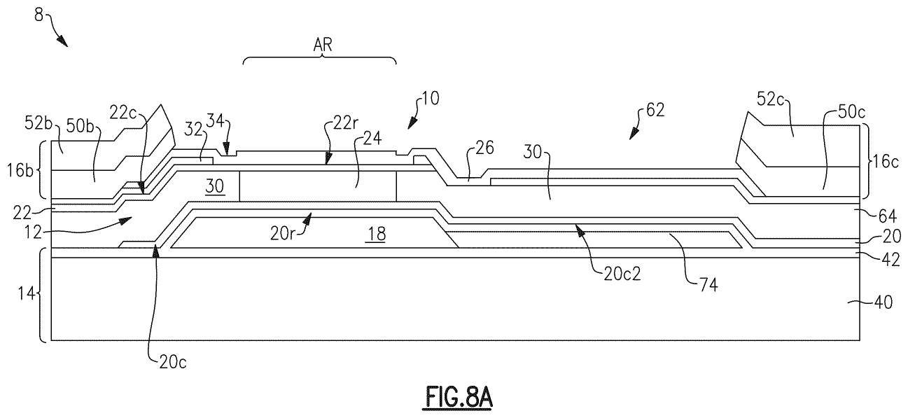

FIG. 9A is an example schematic top plan view of a capacitor integrated BAW device. FIG. 9B is another example schematic top plan view of a capacitor integrated BAW device. In FIGS. 9A and 9B, the acoustically active region AR can be at least partially (e.g., fully) surrounded by a recessed frame structure 34 and the raised frame structure 32. As illustrated, the active region AR can correspond to the majority of the area of the capacitor integrated BAW device. FIG. 9A illustrates the capacitor integrated BAW device with a pentagon shape with curved sides in plan view. A capacitor integrated BAW device in accordance with any suitable principles and advantages disclosed herein can have any other suitable shape in plan view, such as a semi-elliptical shape, a semi-circular shape, a circular shape, an ellipsoid shape, a quadrilateral shape, or a quadrilateral shape with curved sides. For example, the top plan view of FIGS. 9A and 9B can represent the BAW resonator structure 1 of FIG. 1A. The resonator 10 can be positioned in the acoustically active region AR and the capacitor 12 can be positioned at least partially where the raised frame structure 32 and the recessed frame structure 34 are located. The capacitor 12 can extend beyond the raised frame structure 32 in certain embodiments. Moreover, a capacitor 62 in series with the resonator 10 can be positioned laterally relative to the resonator 10.

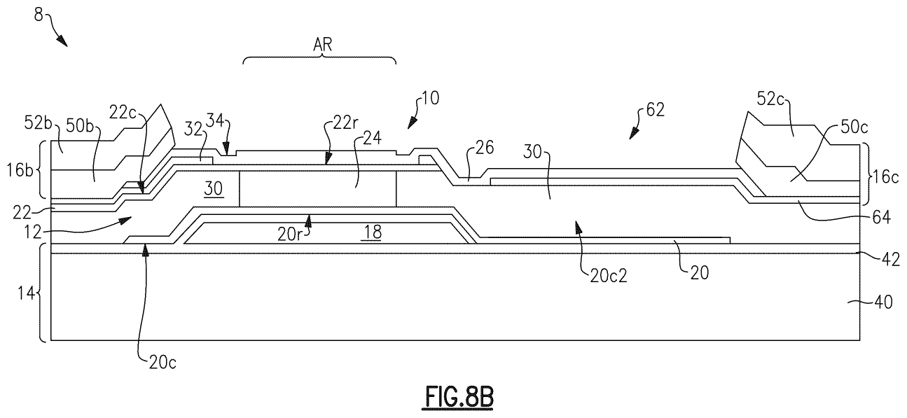

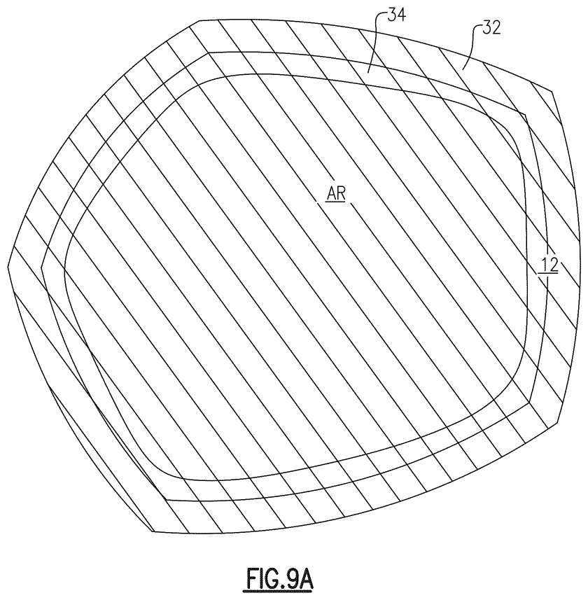

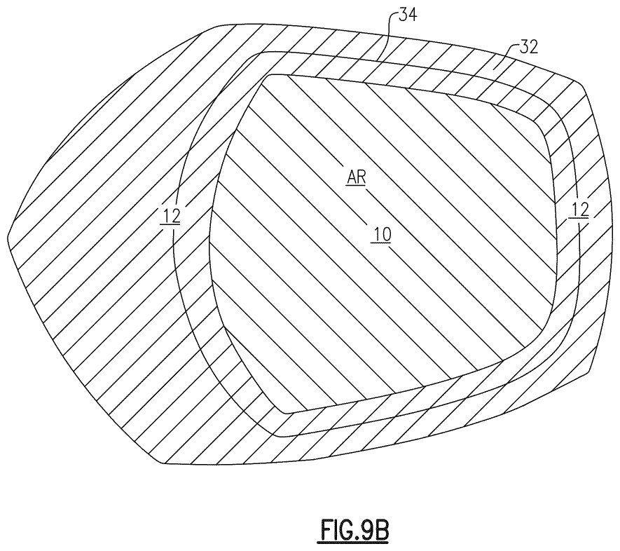

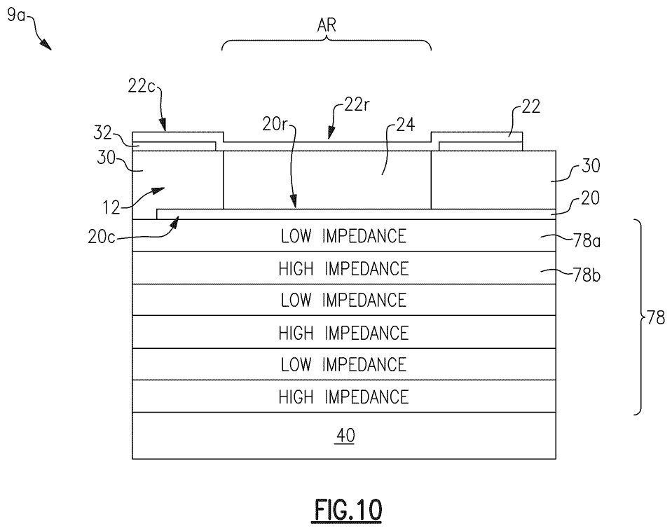

FIG. 10 is an example of a capacitor integrated BAW solidly mounted resonator (SMR) 9a according to an embodiment. FIG. 11 is an example of a capacitor integrated BAW solidly mounted resonator (SMR) 9b according to an embodiment. Unless otherwise noted, the components of the capacitor integrated BAW SMRs 9a, 9b shown in FIGS. 10 and 11 may be structurally and/or functionally the same as or generally similar to like components of other BAW devices disclosed herein. In place of the cavity 18 shown in one or more other figures, the BAW SMR 9a includes a solid acoustic mirror 78 between the support substrate 40 and the first electrode 20. The illustrated acoustic mirror 78 includes acoustic Bragg reflectors. The illustrated acoustic Bragg reflectors can include alternating low impedance layers 78a and high impedance layers 78b. As an example, the Bragg reflectors can include alternating silicon dioxide layers as low impedance layers 78a and tungsten layers as high impedance layers 78b. Any other suitable features of an SMR can alternatively or additionally be implemented. Any other suitable features of BAW devices disclosed herein can be implemented in a BAW SMR.

BAW devices with an integrated capacitor disclosed herein can be implemented in a variety of applications. Applications of these BAW devices include, but are not limited to, a BAW resonator for filter that filters an electrical signal, a BAW oscillator such as a BAW oscillator for a clock generator, a BAW sensor (e.g., a gas sensor, a particle sensor, a mass sensor, a pressure or touch sensor, etc.), a BAW delay line such as BAW delay line for radar and/or instrumentation applications, an actuator, a microphone, and a speaker. Filters that include BAW resonators can be implemented in a variety of applications including, but not limited to, mobile phones, mobile computing devices, base stations, repeaters, relays, wireless communication infrastructure, access points, customer premises equipment (CPE), and distributed antenna systems. BAW oscillators can replace crystal oscillators in a variety of applications, such as but not limited to electronic timing products.

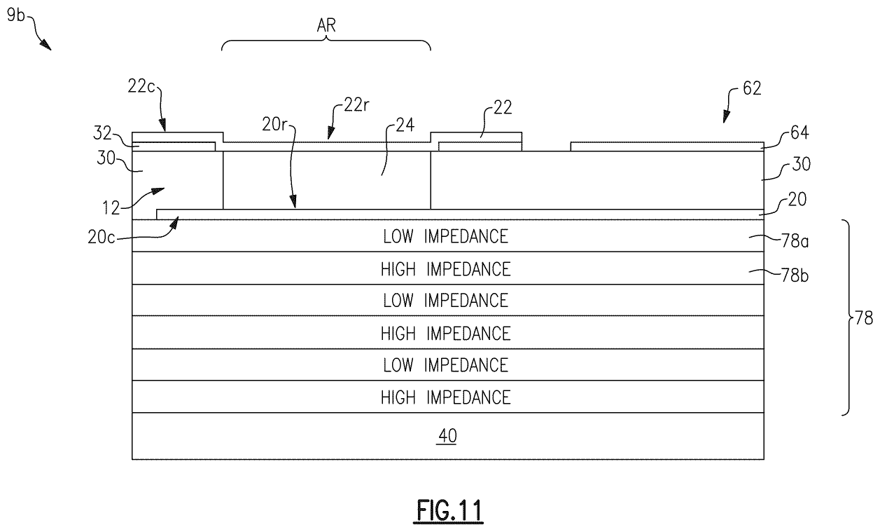

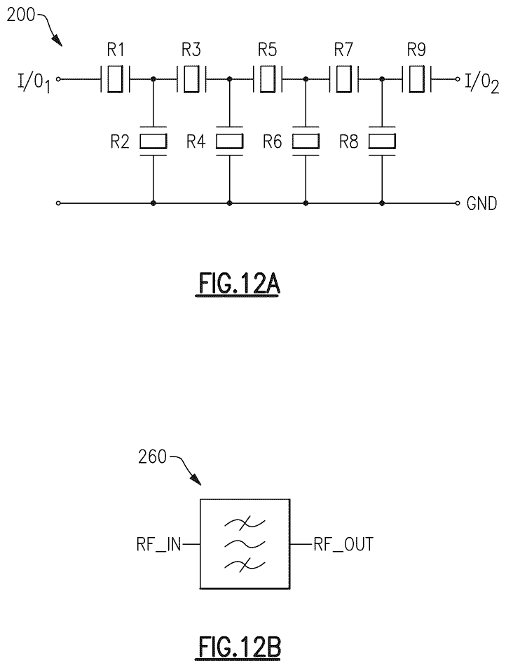

BAW devices disclosed herein can be implemented as BAW resonators in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 12A.

FIG. 12A is a schematic diagram of a ladder filter 200 that includes a BAW resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port. One or more of the acoustic wave resonators of the ladder filter 200 can be a BAW resonator where such a BAW resonator is integrated that with a capacitor in accordance with any suitable principles and advantages disclosed herein. All acoustic resonators of the ladder filter 200 can include a BAW resonator where such a BAW resonator is integrated with a capacitor in accordance with any suitable principles and advantages disclosed herein.

A filter that includes a BAW resonator and an integrated capacitor in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes a BAW resonator and an integrated capacitor in accordance with any suitable principles and advantages disclosed herein can be arranged to filter a radio frequency signal in a fourth generation (4G) Long Term Evolution (LTE) operating band. A filter that includes a BAW resonator and an integrated capacitor in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band. A filter that includes a BAW resonator and an integrated capacitor in accordance with any suitable principles and advantages disclosed herein can be arranged to filter a radio frequency signal in any other suitable operating band, such as a WiFi operating band.

The BAW resonators disclosed herein can be advantageous for implementing BAW devices with relatively high Qp and relatively low spur intensity. BAW resonators disclosed herein can have significantly better performance than a variety of other BAW resonators. This can be advantageous in meeting demanding specifications for acoustic wave filters, such as performance specifications for certain 5G applications.

FIG. 12B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator and an integrated capacitor according to an embodiment.

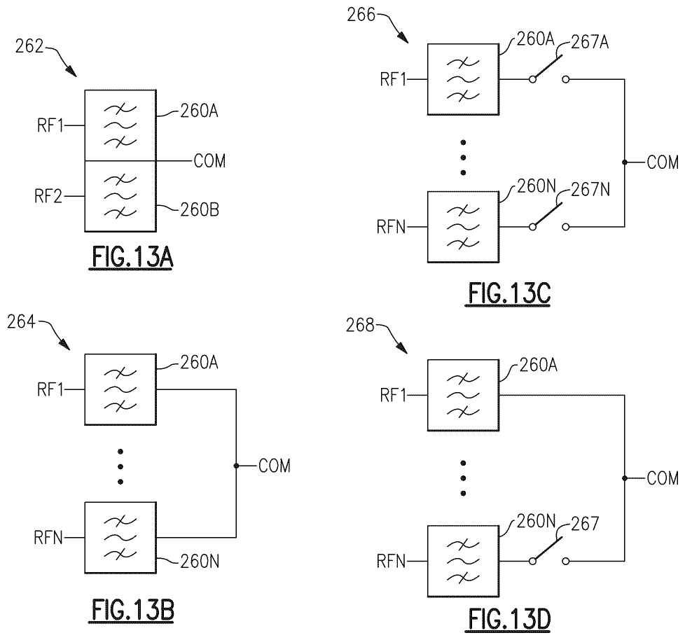

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 13A to 13D. Any suitable principles and advantages of these multiplexers can be implemented together with each other.

FIG. 13A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator and an integrated capacitor in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator and an integrated capacitor in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 13B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator and an integrated capacitor in accordance with any suitable principles and advantages disclosed herein. The other filter(s) of the multiplexer 264 can include one or more acoustic wave filters, one or more acoustic wave filters that include a BAW resonator and an integrated capacitor in accordance with any suitable principles and advantages disclosed herein, one or more LC filters, one or more hybrid acoustic wave LC filters, the like, or any suitable combination thereof.

FIG. 13C is a schematic diagram of a multiplexer 266 that includes an acoustic wave filter according to an embodiment. The multiplexer 266 is like the multiplexer 264 of FIG. 13B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 13D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 14, 15, and 16 are schematic block diagrams of illustrative packaged modules according to certain embodiments. Any suitable combination of features of these packaged modules can be implemented with each other.

FIG. 14 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 14 includes one or more acoustic wave devices 274 and terminals 275A and 275B. The one or more acoustic wave devices 274 include one or more BAW devices with an integrated capacitor implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 14. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

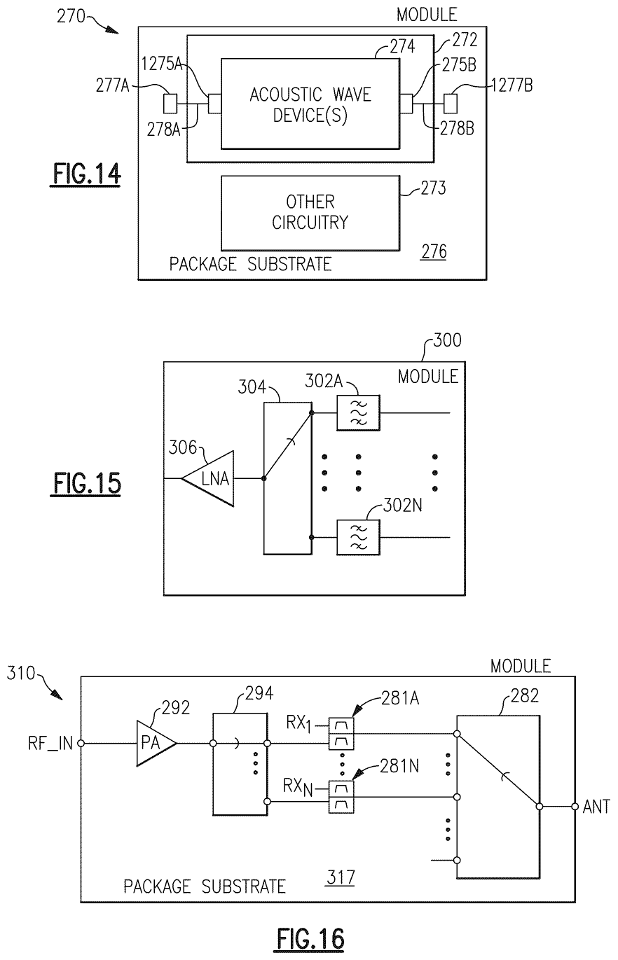

FIG. 15 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices with an integrated capacitor in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 16 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 16 and/or additional elements. The radio frequency module 310 may include any one of the acoustic wave filters that include at least one bulk acoustic wave resonator and an integrated capacitor in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device with an integrated capacitor in accordance with any suitable principles and advantages disclosed herein. Similarly, one or more of the receive filters can include a BAW device with an integrated capacitor in accordance with any suitable principles and advantages disclosed herein. Although FIG. 16 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

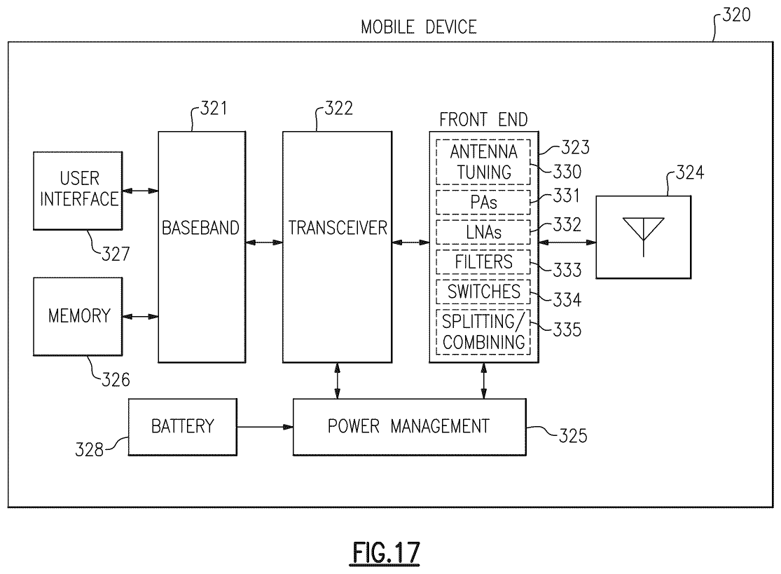

The BAW devices disclosed herein can be implemented in wireless communication devices. FIG. 17 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 17 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAs) 331, low noise amplifiers (LNAs) 332, filters 333, switches 334, and signal splitting/combining circuitry 335. However, other implementations are possible. The filters 333 can include one or more acoustic wave filters that include any suitable number of BAW devices with an integrated capacitor in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 17, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 17, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave resonator structure comprising:
a bulk acoustic wave resonator including an acoustic reflector, a first electrode, a second electrode, a piezoelectric layer positioned between the first electrode and the second electrode, and a frame structure; and
a metal-insulator-metal capacitor in parallel with the bulk acoustic wave resonator, the metal-insulator-metal capacitor including a portion of the first electrode and a portion of the second electrode, and at least part of the metal-insulator-metal capacitor is positioned laterally relative to the acoustic reflector.

2. The bulk acoustic wave resonator structure of claim 1 wherein the metal-insulator-metal capacitor includes an engineered region of the piezoelectric layer positioned between the portion of the first electrode and the portion of the second electrode, and the engineered region of the piezoelectric layer has a lower magnitude effective piezoelectric coefficient than the piezoelectric layer in an acoustically active region of the bulk acoustic wave resonator.

3. The bulk acoustic wave resonator structure of claim 1 wherein the frame structure at least partially overlaps the metal-insulator-metal capacitor.

4. The bulk acoustic wave resonator structure of claim 3 wherein the frame structure includes a raised frame structure.

5. The bulk acoustic wave resonator structure of claim 3 wherein the frame structure is asymmetric about an acoustically active region of the bulk acoustic wave resonator.

6. The bulk acoustic wave resonator structure of claim 1 wherein the frame structure fully overlaps with an insulator of the metal-insulator-metal capacitor.

7. The bulk acoustic wave resonator structure of claim 1 further comprising an interconnect structure at least partially over the metal-insulator-metal capacitor.

8. The bulk acoustic wave resonator structure of claim 1 further comprising a second metal-insulator-metal capacitor in series with the bulk acoustic wave resonator.

9. The bulk acoustic wave resonator structure of claim 8 wherein the second metal-insulator-metal capacitor and the bulk acoustic wave resonator are over a common substrate such that (i) the acoustic reflector is between the common substrate and the piezoelectric layer of the bulk acoustic wave resonator and (ii) the bulk acoustic wave resonator structure is free from the acoustic reflector between the second metal-insulator-metal capacitor and the common substrate.

10. The bulk acoustic wave resonator structure of claim 1 wherein the acoustic reflector is an air cavity.

11. A bulk acoustic wave resonator structure comprising:
a bulk acoustic wave resonator including an acoustic reflector, a resonator portion of a first electrode, a resonator portion of a second electrode, a piezoelectric layer positioned between the resonator portion of the first electrode and the resonator portion of the second electrode, and a frame structure; and
a capacitor including a capacitor portion of the first electrode, a capacitor portion of the second electrode, and an insulator positioned between the capacitor portion of the first electrode and the capacitor portion of the second electrode, at least part of the insulator overlapping with the frame structure, and at least part of the capacitor is positioned laterally relative to the acoustic reflector.

12. The bulk acoustic wave resonator structure of claim 11 wherein the insulator includes an engineered region of the piezoelectric layer, and the engineered region of the piezoelectric layer has a lower magnitude effective piezoelectric coefficient than the piezoelectric layer between the resonator portion of the first electrode and the resonator portion of the second electrode.

13. The bulk acoustic wave resonator structure of claim 11 wherein the frame structure fully overlaps the insulator.

14. The bulk acoustic wave resonator structure of claim 11 wherein the frame structure includes a raised frame structure.

15. The bulk acoustic wave resonator structure of claim 11 further comprising an interconnect structure at least partially overlapping with the capacitor.

16. The bulk acoustic wave resonator structure of claim 11 further comprising a second capacitor in series with the bulk acoustic wave resonator, the second capacitor including a second capacitor portion of one of the first electrode or the second electrode.

17. The bulk acoustic wave resonator structure of claim 16 wherein the second capacitor is non-overlapping with the acoustic reflector.

18. An acoustic wave filter for filtering a radio frequency signal, the acoustic wave filter comprising:
a bulk acoustic wave resonator including an acoustic reflector, a first electrode, a second electrode, a piezoelectric layer positioned between the first electrode and the second electrode, and a frame structure;
a metal-insulator-metal capacitor in parallel with the bulk acoustic wave resonator, the metal-insulator-metal capacitor including a portion of the first electrode and a portion of the second electrode, and at least part of the metal-insulator-metal capacitor is positioned laterally relative to the acoustic reflector; and
a plurality of additional acoustic wave resonators, the bulk acoustic wave resonator and the plurality of additional acoustic wave resonators configured to filter the radio frequency signal.

19. The acoustic wave filter of claim 18 further comprising a second metal-insulator-metal capacitor in series with the bulk acoustic wave resonator; and the bulk acoustic wave resonator, the metal-insulator-metal capacitor, and second metal-insulator-metal capacitor are over a common substrate.

20. The acoustic wave filter of claim 18 wherein the radio frequency signal is a New Radio signal.
